(19) United States
(12) Patent Application Publication
(10) Pub. No.: US 2022/0336723 A1
(43) Pub. Date: Oct. 20, 2022

(54) IN-CHIP THERMOELECTRIC DEVICE

(71) Applicant: Taiwan Semiconductor Manufacturing Company, Ltd., Hsinchu (TW)

(72) Inventor: Jen-Yuan Chang, Hsinchu (TW)

(21) Appl. No.: 17/393,345

(22) Filed: Aug. 3, 2021

Related U.S. Application Data
(60) Provisional application No. 63/176,165, filed on Apr. 16, 2021.

(51) Int. Cl. H01L 35/28; H01L 35/10; H01L 23/498; G01K 7/02

(52) U.S. Cl. CPC H01L 35/28; H01L 35/10; H01L 23/49827; G01K 7/021

(57) ABSTRACT

An semiconductor device includes a substrate having a first surface and a second surface opposite the first surface, and a through-silicon via structure extending through the substrate. The through-silicon via structure includes a first through-silicon via containing a first conductivity type material and a second through-silicon via containing a second conductivity type material opposite the first conductivity type material. The semiconductor device also includes a first conductive layer on the first surface of the substrate and electrically coupled to a first end of the first through-silicon via and a first end of the second through-silicon via. The semiconductor device also includes a second conductive on the second surface and having a first portion coupled to a second end of the first through-silicon via and a second portion coupled to a second end of the second through-silicon via.

### CROSS-REFERENCES TO RELATED APPLICATIONS

The present application claims priority to U.S. Provisional Patent Application No. 63/176,165, filed on Apr. 16, 2021, the entire disclosure of which is incorporated herein by reference.

### BACKGROUND

Advances in technology enable semiconductor devices to operate at increased speeds and with increased power levels. The increased speeds and power levels can cause the temperature in the semiconductor devices to increase. Temperature sensors are used to monitor the temperature of semiconductor devices, and temperature information may be provided to a controller to take corrective action. Temperature sensors generally include a pn junction forming a diode that is forward biased, and the current flowing through the diode is a function of the temperature at the pn junction. Thermistors have a resistance that varies with temperature and can be used as temperature sensors. In general, temperature sensors are disposed externally to semiconductor devices and cannot directly determine the temperature inside the semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrary increased or reduced for clarity of discussion.

FIG. 1A and FIG. 1B are cross-sectional views illustrating a thermoelectric device having a Peltier-Seebeck effect for explaining embodiments of the present disclosure.

FIG. 2A is a perspective view of a semiconductor device including a thermoelectric device according to some embodiments.

FIG. 2B is a cross-sectional view of the semiconductor device including the thermoelectric device in FIG. 2A taken along the line A-A.

FIG. 3A is a cross-sectional view of the semiconductor device including the thermoelectric device according to some embodiments.

FIG. 3B is a cross-sectional view of a thermoelectric device according to an exemplary embodiment.

FIG. 4A is a cross-sectional view of an apparatus according to an exemplary embodiment.

FIG. 4B is a simplified block circuit diagram of a detection circuit according to an exemplary embodiment.

FIG. 5 is a simplified flowchart illustrating a method of operating an apparatus according to an exemplary embodiment.

FIG. 6A is a top view of a motherboard including a central processing unit (CPU), a dynamic random access memory (DRAM), and capacitance known in the art.

FIG. 6B is a top view of a motherboard including a central processing unit (CPU), a dynamic random access memory (DRAM), and capacitance according to an exemplary embodiment.

FIG. 7 is a cross-sectional view illustrating a semiconductor device according to some embodiments.

FIG. 8 is a cross-sectional view illustrating a semiconductor device according to some embodiments.

FIG. 9 is a diagram illustrating operation steps of a cooling apparatus according to an exemplary embodiment.

FIG. 10 is a cross-sectional view illustrating a semiconductor device including a thermoelectric device and a detection circuit according to some embodiments.

### DETAILED DESCRIPTION OF THE INVENTION

The following disclosure provides many different embodiments or examples for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. The term vertical, as used herein, means substantially perpendicular to the surface of a substrate. The terms “first,” “second,” “third,” and “fourth” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Numerous benefits and advantages are achieved by way of the present disclosure over conventional techniques. For example, embodiments provide a thermoelectric device that can be embedded in a semiconductor device for accurately detecting a temperature increase of the semiconductor device and for taking corrective action before the temperature increase causes damage to the semiconductor device. The thermoelectric device can also be configured as a cooling device to reduce a temperature of the semiconductor device. The thermoelectric device has a small dimension so that it can be disposed in a vicinity of an active region of the semiconductor device. The thermoelectric device is compatible with existing semiconductor manufacturing processes and can be fabricated concurrently with the fabrication of the semiconductor device. These and other embodiments of the disclosure, along with many of its advantages and features, are described in more detail in conjunction with the text below and corresponding figures.

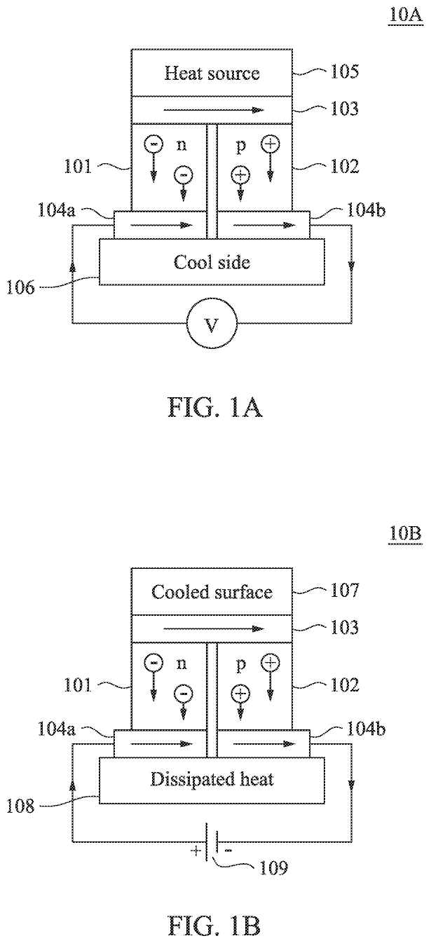

FIG. 1A and FIG. 1B are cross-sectional views illustrating a thermoelectric device having a Peltier-Seebeck effect for explaining embodiments of the present disclosure. The Peltier-Seebeck effect is the direct conversion of temperature difference to electric voltage and vice versa. The thermoelectric device creates a voltage when there is a different temperature on each side of the thermoelectric device. An applied temperature gradient causes charge carriers in the material to diffuse from the hot side (heat source) to the cool side. This effect can be used to measure temperature of an object. Because the direction of heating and cooling is controlled by the polarity of the applied voltage, the thermoelectric device can be used as a temperature controller.

FIG. 1A is a cross-sectional views illustrating a thermoelectric device 10A operating as a temperature sensor. Referring to FIG. 1A, the thermoelectric device 10A includes an n-doped semiconductor 101, a p-doped semiconductor 102, a first conductive layer 103 coupled to an upper surface of the n-doped semiconductor 101 and an upper surface of the p-doped semiconductor 102, and a second conductor layer having a first portion 104a coupled to a lower surface of the n-doped semiconductor 101 and a second portion 104b coupled to a lower portion of the p-doped semiconductor 102. The thermoelectric device 10A is arranged between a heat source 105 and a cool side 106. The heat source can be a semiconductor device operating at a clock frequency, and the cool side 106 can be a package substrate, a printed-circuit board (PCB), a silicon interposer, or the like. A temperature difference between the heat source 105 and the cool side 106 causes charge carriers in the n-doped semiconductor 101 and the p-doped semiconductor 102 to diffuse from the hot side to the cool side, and a voltage V is generated between the lower portions of the p-doped semiconductor 102 and the n-doped semiconductor 101. When a voltmeter or an ammeter (ampere meter) is placed between the lower portions of the p-doped semiconductor 102 and the n-doped semiconductor 101, the thermoelectric device 10A operates as a temperature sensor.

FIG. 1B is a cross-sectional view illustrating a thermoelectric device 10B operating as a thermoelectric cooling device. Referring to FIG. 1B, the thermoelectric device 10B includes an n-doped semiconductor 101, a p-doped semiconductor 102, a first conductive layer 103 coupled to an upper surface of the n-doped semiconductor 101 and an upper surface of the p-doped semiconductor 102, and a second conductor layer having a first portion 104a coupled to a lower surface of the n-doped semiconductor 101 and a second portion 104b coupled to a lower portion of the p-doped semiconductor 102. The thermoelectric device 10B is arranged between a cooled surface 107 and a heat dissipating surface 108. When a voltage source 109 is applied between the n-doped semiconductor 101 and the p-doped semiconductor 102, heat is transferred from the cooled surface 107 to the heat dissipating surface 108, creating a temperature difference between the cooled surface 107 and the heat dissipating surface 108. This effect can be used to lower the temperature of the cooled surface 107. The thermoelectric device 10B operates as a thermoelectric cooling device.

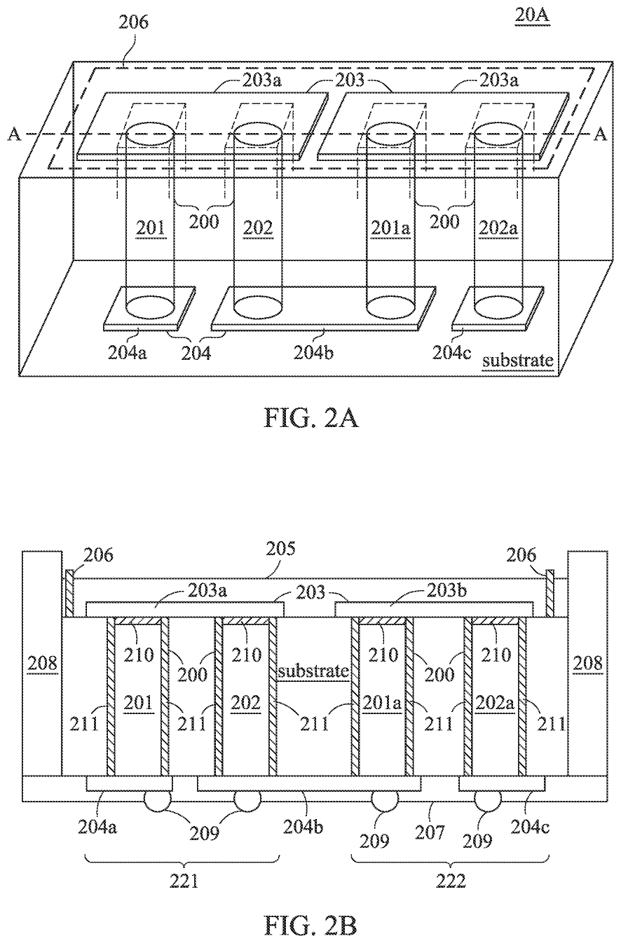

FIG. 2A is a perspective view of a semiconductor device 20A including a thermoelectric device according to some embodiments. Referring to FIG. 2A, the semiconductor device 20A includes a through-silicon via (TSV) structure 200 extending through a substrate. The substrate may include a bulk silicon substrate or a non-semiconductor substrate. Alternatively, the substrate may include an elementary semiconductor, such as silicon or germanium in a crystalline structure, a compound semiconductor, e.g., silicon germanium, silicon carbide, gallium arsenic, gallium phosphide, indium phosphide, indium arsenide, indium antimonide, or combinations thereof. The substrate may also include a semiconductor-on-insulator (SOI) substrate. In an embodiment, the substrate is a silicon layer of an SOI substrate. The substrate can include various doped regions depending on design requirements, e.g., n-type wells and/or p-type wells. The doped regions are doped with p-type dopants, e.g., boron, n-type dopants, e.g., phosphorous, arsenic, or combinations thereof. The doped regions may be formed directly on the substrate, in a P-well structure, in an N-well structure, in a dual-well structure, on a raised structure, or in a raised structure. The substrate may also include various active regions for forming N-type metal-oxide semiconductor transistor (NMOS) devices and P-type metal-oxide semiconductor transistor (PMOS) devices. The through-silicon via (TSV) structure 200 includes a first through-silicon via (TSV) 201 containing a first conductivity type material and a second TSV 202 containing a second conductivity type material opposite the first conductivity type material. In an embodiment, the first conductivity type material includes an n-type doped material, and the second conductivity type material includes a p-type doped material. The first and second through-silicon vias 201 and 202 may have a cylindrical shape extending from an upper surface of the substrate to a lower surface of the substrate. In an embodiment, the first and second through-silicon vias 201 and 202 may have a circular cross-section. In an embodiment, the first and second through-silicon vias 201 and 202 may have a rectangular cross-section, as indicated by dotted lines in FIG. 2A. In some embodiments, the first and second through-silicon vias 201 and 202 may have other shaped cross-sections, such as oval, square, and other polygonal-shaped cross-sections.

The semiconductor device 20A also includes a first conductive layer 203 on the upper surface of the substrate and having a first portion 203a electrically coupled to the upper portion of the first and second TSVs 201 and 202. The first conductive layer 203 can include aluminum (Al), copper (Cu), tungsten (W), platinum (Pt), silver (Ag), or highly doped polysilicon. The semiconductor device 20A further includes a second conductive layer 204 disposed on the lower surface of the substrate. The second conductive layer 204 can include aluminum (Al), copper (Cu), tungsten (W), platinum (Pt), silver (Ag), or highly doped polysilicon. The second conductive layer 204 includes a first portion 204a electrically coupled to the lower portion of the first TSV 201 and a second portion 204b electrically coupled to the lower portion of the second TSV 202.

In some embodiments, the through-silicon via (TSV) structure 200 can further include a third TSV 201a containing the first conductivity type material and a fourth TSV 202a containing the second conductivity type material. The third TSV 201a has an upper portion electrically coupled to a second portion 203b of the first conductive layer 203, and the fourth TSV 202a has an upper portion electrically coupled to the second portion 203b of the first conductive layer 203. The third TSV 201a has a lower portion electrically coupled to the second portion 204b of the second conductive layer 204, and the fourth TSV 202a has a lower portion electrically coupled to a third portion 204c of the second conductive layer 204. The first, second, and third portions 204a, 204b, 204c of the second conductive layer 204 are electrically separated from each other. In an embodiment, the first and third TVSs 201 and 201a each include a doped silicon material containing n-type dopants, such as nitrogen (N), phosphorous (P), arsenic (As), or combinations thereof with a doping concentration greater than 1E17 (1×10¹⁷) atoms/cm³. The second and fourth TSVs 202 and 202a each include a doped silicon material containing p-type dopants, such as boron (B), aluminum (Al), gallium (Ga) or combinations thereof with a doping concentration greater than 1E17 (1×10¹⁷) atoms/cm³.

In some embodiments, the semiconductor device 20A also include a seal ring 206 disposed on the upper surface of the substrate surrounding the through-silicon via (TSV) structure 200. The seal ring 206 is configured to shield the thermoelectric device from noises generated by active devices in the semiconductor device 20A. The seal ring 206 includes one or more layers of metal, such as copper (Cu), aluminum (Al), tungsten (W), or a highly doped semiconductor material, such as n-type doped silicon, p-type doped silicon, n-type doped polysilicon, p-type doped polysilicon, or combinations thereof. In an embodiment, the seal ring 206 is connected to a DC power supply. In an embodiment, the seal ring 206 is connected to ground. In an embodiment, the seal ring 206 is in a floating state.

FIG. 2B is a cross-sectional view of the semiconductor device 20A including the thermoelectric device of FIG. 2A taken along the line A-A. Referring to FIG. 2B, the thermoelectric device includes the through-silicon via structure 200 extending through the substrate; the through-silicon via structure includes the first TSV 201 having the upper portion coupled to the first portion 203a of the first conductive layer 203 and a lower portion coupled to the first portion 204a of the second conductive layer 204, the second TSV 202 having the upper portion coupled to the first portion 203a of the first conductive layer 203 and the lower portion coupled to the second portion 204b of the second conductive layer 204, the third TSV 201a having the upper portion coupled to the second portion 203b of the first conductive layer 203 and the lower portion coupled to the second portion 204b of the second conductive layer 204, and the fourth TSV 202a having the upper portion coupled to the second portion 203b of the first conductive layer 203 and the lower portion coupled to the third portion 204c of the second conductive layer 204. The first and second portions 203a and 203b of the first conductive layer 203 are electrically separated from each other. The first, second, and third portions 204a, 204b, and 204c of the second conductive layer 204 are electrically separated from each other. In an embodiment, the first TSV 201, the second TSV 202, the first portion 203a of the first conductive layer 203, and the first portion 204a of the second conductive layer 204 form a first thermoelectric device 221. The third TSV 201a, the fourth TSV 202a, the second portion 203b of the first conductive layer 203, and the second portion 204b and the third portion 204c of the second conductive layer 204 form a second thermoelectric device 222. The first thermoelectric device 221 and the second thermoelectric device 222 are connected in series to form a serial connected thermoelectric sensor. The serial connection of two thermoelectric devices can increase the electrical signal level of the thermoelectric sensor. It is understood that the number of thermoelectric devices can be any integer number. In the example shown in FIGS. 2A and 2B, two thermoelectric devices are used, but it is understood that the number is illustrative only for describing the example embodiment and should not be limiting.

Referring still to FIG. 2B, the semiconductor device 20A also includes at least one intermetal dielectric layer 205 on the first conductive layer 203 and on the upper surface of the substrate. In an embodiment, the seal ring 206 extends through the at least one intermetal dielectric layer 205 to the substrate. The semiconductor device 20A also includes at least one bonding layer 207 on the second conductive layer 204 and on the lower surface of the substrate, and an around-die dielectric layer 208 surrounding the substrate. The around-die dielectric layer 208 includes tetraethyl orthosilicate (TEOS), silicon oxide (SiO₂), and the like. In an embodiment, the at least one intermetal dielectric layer 205 includes phosphosilicate glass (PSG) or silicon dioxide (SiO₂). The at least one bonding layer 207 includes silicon oxide. In an embodiment, the semiconductor device 20A also includes a plurality of under bump metal pads 209 coupled to the first, second, and third portions of the second conductive layer 204. In an embodiment, electrical signals generated by a temperature difference between the first and second conductive layers 203 and 204 are provided to an external measurement device (e.g., voltmeter, anmeter) via the under bump metal pads 209 for monitoring, or to a controller for processing.

In some embodiments, the semiconductor device 20A also includes a metal silicide layer 210 disposed between the upper surface of the first, second, third, and fourth TSVs 201, 202, 201a, and 202a and the first conductive layer 203. The metal silicide layer 210 includes at least one metal selected from titanium (Ti), tungsten (W), cobalt (Co), nickel (Ni), hafnium (Hf), platinum (Pt), and tantalum (Ta). In an exemplary embodiment, the metal silicide layer 210 includes CoSi, NiSi, or a combination thereof. In some embodiments, the semiconductor device 20A also includes a dielectric liner 211 disposed between sidewalls of the through-silicon via structure 200 and the substrate. The dielectric liner 211 includes silicon oxide.

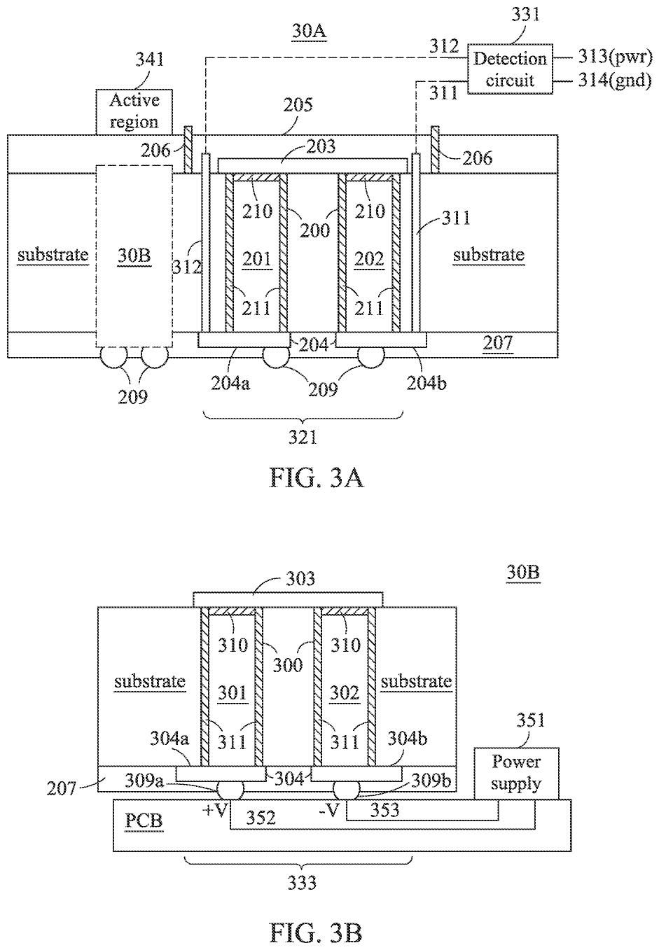

FIG. 3A is a cross-sectional view of a semiconductor device 30A including a thermoelectric device 321 according to some embodiments. Referring to FIG. 30A, the semiconductor device 30A is similar to the semiconductor device 20A except for the difference described herein. In an embodiment, the semiconductor device 30A may include a detection circuit for measurement or monitoring a temperature of a region of the semiconductor device 30A. In an embodiment, the semiconductor device 30A may include a thermoelectric cooling device disposed in the vicinity of an active region to cool the active region. Accordingly, description in relation to the elements illustrated in FIGS. 2A and 2B is applicable to the elements in FIG. 3A as appropriate. In an exemplary embodiment, the thermoelectric device 321 is similar or the same as the thermoelectric device 221 of FIGS. 2A and 2B. The thermoelectric device 321 includes the through-silicon via structure 200 extending through the substrate, the through-silicon via structure 200 includes the first TSV 201 having the upper portion coupled to the first conductive layer 203 and the lower portion coupled to the first portion 204a of the second conductive layer 204, the second TSV 202 having the upper portion coupled to the first conductive layer 203 and the lower portion coupled to the second portion 204b of the second conductive layer 204. The first and second portions 204a and 204b of the second conductive layer 204 are electrically separated from each other. The TSV 201 includes a doped silicon material containing n-type dopants, such as nitrogen (N), phosphorous (P), arsenic (As), or combinations thereof with a doping concentration greater than 1E17 (1×10¹⁷) atoms/cm³. The second TSV 202 includes a doped silicon material containing p-type dopants, such as boron (B), aluminum (Al), gallium (Ga) or combinations thereof with a doping concentration greater than 1E17 (1×10¹⁷) atoms/cm³.

The semiconductor device 30A also includes an intermetal dielectric layer 205 on the first conductive layer 203 and on the upper surface of the substrate, the seal ring 206 extending through the at least one intermetal dielectric layer 205 to the substrate and surrounding at least the upper surface of the thermoelectric device 321. The semiconductor device 30A also includes at least one bonding layer 207 on the second conductive layer 204 and on the lower surface of the substrate. The semiconductor device 30A also includes a first through oxide via (TOV) 311 formed on the second portion 204b of the second conductive layer 204 and extending through the substrate and cross a portion of the at least one intermetal dielectric layer 205 and electrically coupled to a detection circuit 331 that is disposed on the at least one intermetal dielectric layer 205. The semiconductor device 30A also includes a second through oxide via (TOV) 312 formed on the first portion 204a of the second conductive layer 204 and extending through the substrate and cross a portion of the at least one intermetal dielectric layer 205 and electrically coupled to the detection circuit 331. That is, the first and second TOVs 311, 312 cross the substrate to electrically coupled the bottom portions of the through-silicon via structure 200 to the detection circuit 331 which is configured to determine or measure an electrical signal generated by the thermoelectric device 321 when a temperature difference is present between the upper portion and the lower portion of the thermoelectric device 321. In an embodiment, the first and second TOVs 311, 312 cross the substrate and other package substrate or interposer that are coupled to the substrate. The first and second TOVs 311, 312 each include aluminum, copper, tungsten, or highly doped polysilicon. In an embodiment, the detection circuit 331 includes power terminals connected to a power source 313 and a ground 314. In an embodiment, the seal ring is electrically coupled to the power source 313. In an embodiment, the seal ring is electrically coupled to the ground 314. In an embodiment, the seal ring is in a floating state. In an embodiment, the detection circuit 331 includes an operational amplifier for amplifying an electrical signal generated by the thermoelectric device 221. In an embodiment, the detection circuit 331 also includes a comparison circuit for comparing the amplified electrical signal with a reference threshold to determine a level of the amplified electrical signal which is a function of the temperature difference between the upper portion and the lower portion of the thermoelectric device 321. In an embodiment, the semiconductor device 30A also includes a controller configured to take corrective measures in response to a comparison result provided by the comparison circuit.

In some embodiments, the thermoelectric device 321 is disposed in a vicinity of an active region 341 to accurately monitoring a temperature of the active region 341. This closely thermal coupling to the active region 341 is possible because the thermoelectric device 321 has a compact size and is noise shielded by the seal ring 206. As described in connection with FIGS. 2A and 2B, the electrical signal level of the thermoelectric device 321 can be increased by connecting several thermoelectric devices in series. The seal ring 206 enables a placement of the thermoelectric device 221 in a vicinity of the active region 341. That is, the seal ring 206 is configured to substantially shield an electrical signal generated by the thermoelectric device 321 from electromagnetic signals or noises generated in the active region 341. In an exemplary embodiment, the active region 341 can include a graphics processing unit (GPU) containing a plurality of parallel processing units and a plurality of memory devices associated to the parallel processing units. In another exemplary embodiment, the active region 341 can include a controller device and a stack of high bandwidth memory devices. In some embodiments, a thermoelectric cooling device 30B is placed in close proximity to the active region 341 to cool the active region by transferring heat from the active region to the bonding layer 207, the bumps 209, and finally to a PCB (not shown) via the bumps 209.

FIG. 3B is a cross-sectional view of a thermoelectric cooling device 30B according to an exemplary embodiment. Referring to FIG. 3B, the thermoelectric device 30B has a through-silicon via structure 300 extending through the substrate, the through-silicon via (TVS) structure 300 includes a first TSV 301 having an upper portion coupled to a first conductive layer 303. The through-silicon via structure 300 can be formed at the same time as the through-silicon via structure 200. The first conductive layer 303 can be formed at the same time as the first conductive layer 203. In an embodiment, the first conductive layer 303 is the same first conductive layer 203. The first TSV 301 also includes a lower portion coupled to a first portion 304a of a second conductive layer 304. The through-silicon via (TVS) structure 300 also includes a second TSV 302 having an upper portion coupled to the first conductive layer 303 and a lower portion coupled to a second portion 304b of the second conductive layer 304. The first and second portions 304a and 304b of the second conductive layer 304 are electrically separated from each other. The second conductive layer 304 can be formed concurrently with the second conductive layer 204. In an embodiment, the second conductive layer 304 is the same as the second semiconductor layer 204. The first TVS 301 includes a doped silicon material containing n-type dopants, such as nitrogen (N), phosphorous (P), arsenic (As), or combinations thereof with a doping concentration greater than 1E17 (1×10¹⁷) atoms/cm³. The second TSV 302 includes a doped silicon material containing p-type dopants, such as boron (B), aluminum (Al), gallium (Ga) or combinations thereof with a doping concentration greater than 1E17 (1×10¹⁷) atoms/cm³.

The thermoelectric cooling device 30B also includes a first under bump metal (UBM) pad 309a coupled to the lower portion of the first TVS 301 through the first portion 304a of the second conductive layer 304, and a second UBM pad 309b coupled to the lower portion of the second TVS 302 through the second portion 304b of the second conductive layer 304. The first and second UBM pads 309a, 309b are electrically coupled to a power supply 351 through conductive wirings 352, 353 disposed in and/or on a printed circuit board (PCB). In an embodiment, the first and second UBM pads 309a, 309b are part of the bumps 209 or fabricated concurrently with the bumps 209. By applying a voltage to the first and second portions 304a (+V), 304b (−V) of the second conductive layer 304, a heat transfer from the upper portion to the bottom portion of the thermoelectric cooling device 30B is obtained. In an embodiment, the first TVS 301, the second TVS 302, the first semiconductor layer 303, the first and second portions 304a, 304b of the second conductive layer 304, and the first and second UBM pads 309a, 309b form a thermoelectric cooling device 333.

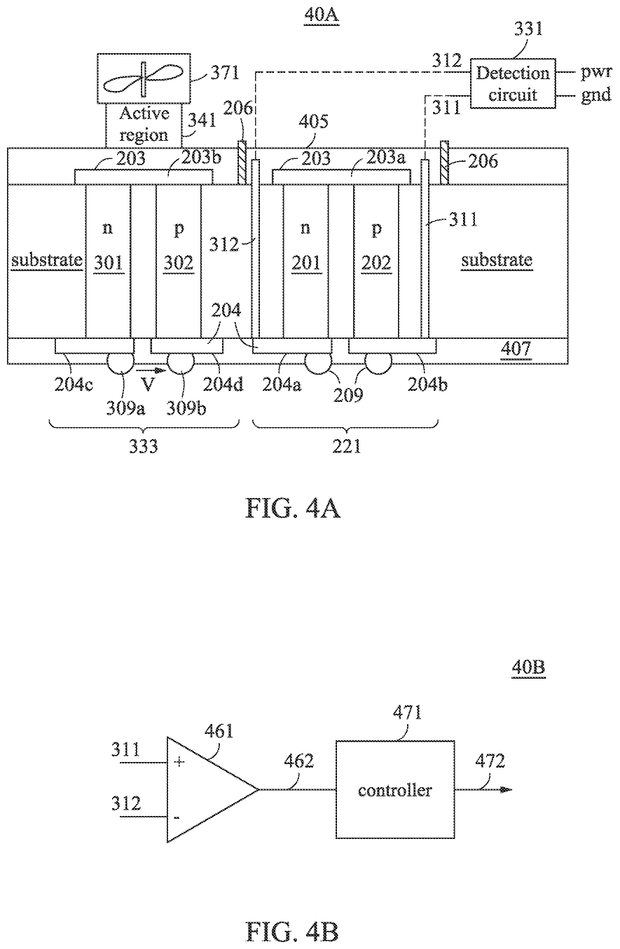

FIG. 4A is a cross-sectional view of an apparatus 40A according to an exemplary embodiment. Referring to FIG. 4A, the apparatus 40A includes a substrate, a thermoelectric sensor 221, a thermoelectric cooler 333, and at least one intermetal dielectric layer 405 on the substrate, the thermoelectric sensor, and the thermoelectric cooler. The thermoelectric sensor 221 includes a first through-substrate via (TSV) 201 containing an n-doped material, a second TSV 202 containing a p-doped material, a first conductive layer 203 having a first portion 203a electrically coupled the upper portions of the first TVS 201 and the second TSV 202, a second conductive layer 204 having a first portion 204a electrically coupled to a bottom portion of the first TSV 201 and a second portion 204b electrically coupled to a bottom portion of the second TVS 202. The thermoelectric cooler 321 includes a first through-substrate via (TSV) 301 containing an n-doped material, a second TSV 302 containing a p-doped material, a second portion 203b of the first conductive layer 203 electrically coupled the upper portions of the first TSV 301 and the second TSV 302, a third portion 204c of the second conductive layer 204 electrically coupled to a bottom portion of the first TSV 301 and a fourth portion 204d of the second conductive layer 204 electrically coupled to a bottom portion of the second TSV 302. The apparatus 40A also includes at least one bonding layer 407 on the bottom surface of the substrate and on the second conductive layer including the first, second, third, and fourth portions 204a, 204b, 204c, and 204d. The first, second, third, and fourth portions 204a, 204b, 204c, and 204d of the second conductive layer are electrically separated and isolated from each other.

In some embodiment, the apparatus 40A also includes a first through oxide via (TOV) 311 formed on the second portion 204b of the second conductive layer 204 and extending through the substrate and cross a portion of the at least one intermetal dielectric layer 205 and electrically coupled to a detection circuit 331. The apparatus 40A also includes a second through oxide via (TOV) 312 formed on the first portion 204a of the second conductive layer 204 and extending through the substrate and cross a portion of the at least one intermetal dielectric layer 405 and electrically coupled to the detection circuit 331. The detection circuit 331 has a first input terminal electrically coupled to the first TOV 311 and a second input terminal electrically coupled to the second TOV 312. The detection circuit 331 is configured to determine or measure an electrical signal generated by the thermoelectric device 221 when a temperature difference is present between the upper portion and the lower portion of the thermoelectric device 221.

In an embodiment, the apparatus 40A further includes a seal ring 206 disposed on the upper surface of the substrate and surrounding the thermoelectric device 221. The seal ring 206 is configured to shield the thermoelectric device 221 from noises and electromagnetic signals generated by active devices in an active region 341. The seal ring 206 includes one or more layers of metal, such as cupper (Cu), aluminum (Al), tungsten (W), or a highly doped semiconductor material, such as n-type doped silicon, p-type doped silicon, n-type doped polysilicon, p-type doped polysilicon, or combinations thereof. In an embodiment, the seal ring 206 is connected to a DC power supply. In an embodiment, the seal ring 206 is connected to ground. In an embodiment, the seal ring 206 is floating.

FIG. 4B is a simplified block circuit diagram of a detection circuit 40B according to an exemplary embodiment. Referring to FIG. 4B, the detection circuit 40B includes an operational amplifier 461 having a first input terminal electrically coupled to the first TOV 311, a second input terminal electrically coupled to the second TOV 312, and an output terminal coupled to a controller 471. In an embodiment, the operational amplifier 461 is a differential operational amplifier configured to amplified a differential signal applied to its input terminals, and provide an electrical signal 462 to the controller 471 for further processing. In an embodiment, the controller 471 is a microcontroller including a comparator, an analog-to-digital converter, a processing unit, and a memory device. The controller 471 is configured to compare the electrical signal 462 with a reference threshold to obtain a comparison result and provide at least one control signal 472 to activate an electric fan 371 mounted on an active device in the active region 341 based on the comparison result, e.g., when the electrical signal 462 is greater than a first predetermined threshold. In an embodiment, the active device can be a graphics processing unit (GPU) having a plurality of parallel processing units and a plurality of memory devices associated with the processing units. In an embodiment, the active device can be a stack of high bandwidth memory devices. In an embodiment, the controller 471 can provide the control signal 472 to activate the thermoelectric cooler 321 based on the comparison result, e.g., when the electrical signal 462 is greater than a second predetermined threshold, which is greater than the first predetermined threshold. In an embodiment, the controller 471 activates the thermoelectric cooler 321 by providing a voltage V to the UBM pads 309a and 309b.

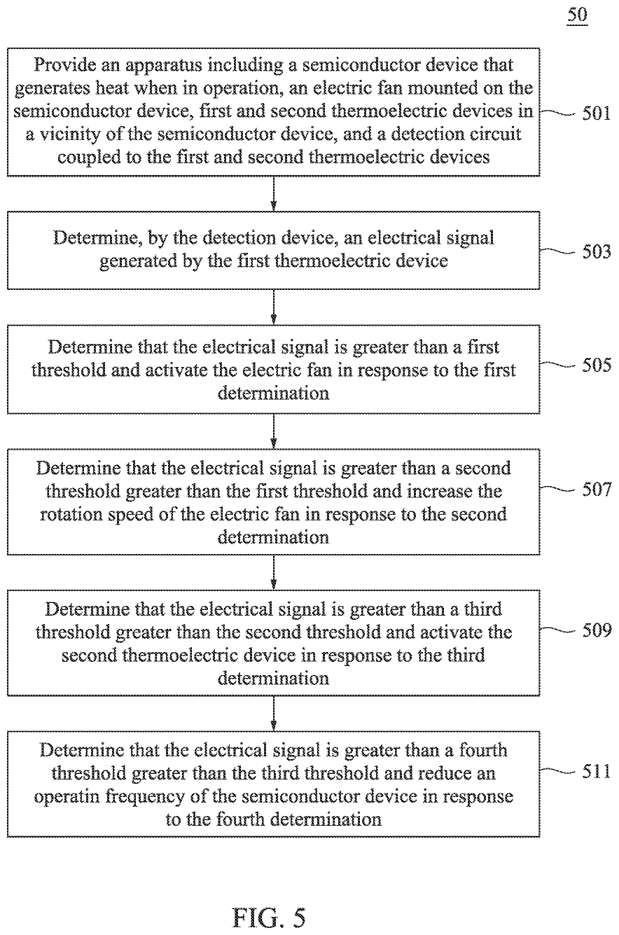

FIG. 5 is a simplified flowchart illustrating a method 50 of operation an apparatus according to an exemplary embodiment. Referring to FIG. 5, the method 50 includes providing an apparatus having a semiconductor device that generates heat when in operation, an electric fan mounted on the semiconductor device, first and second thermoelectric devices disposed in a vicinity of the semiconductor device, and a detection circuit electrically coupled to the first and second thermoelectric devices (block 501). The method 50 also includes determining, by the detection device, an electrical signal generated by the first thermoelectric device (block 503). The electrical signal is a function of a temperature difference between the distal ends (e.g., upper surface and lower surface) of the first thermoelectric device. The method also includes activating the electric fan when determining that the electrical signal is greater than a first predetermined threshold (block 505). The method further includes increasing the rotation speed of the electric fan when determining that the magnitude of the electrical signal exceeds a second predetermined threshold that is greater than the first predetermined threshold (block 507). The method also includes activating the second thermoelectric device when determining that the magnitude of the electrical signal exceeds a third predetermined threshold that is greater than the second predetermined threshold (block 509). The method further includes reducing an operating frequency of the semiconductor device when determining that the magnitude of the electrical signal exceeds a fourth predetermined threshold that is greater than the third predetermined threshold (block 511). For example, the semiconductor device can be a graphics processing unit (GPU) including a plurality of parallel processing units and a plurality of memory devices associated with the parallel processing units, the GPU is disposed in an active region in a vicinity of the first and second thermoelectric devices and running at a certain clock frequency. The detection device can be the detection circuit 40B of FIG. 4B. The first thermoelectric device can be the thermoelectric device 221 shown and described in FIGS. 2B, 3A, 3B, and 4A. The second thermoelectric device can be the thermoelectric cooler 321 shown and described in FIGS. 3B and 4A.

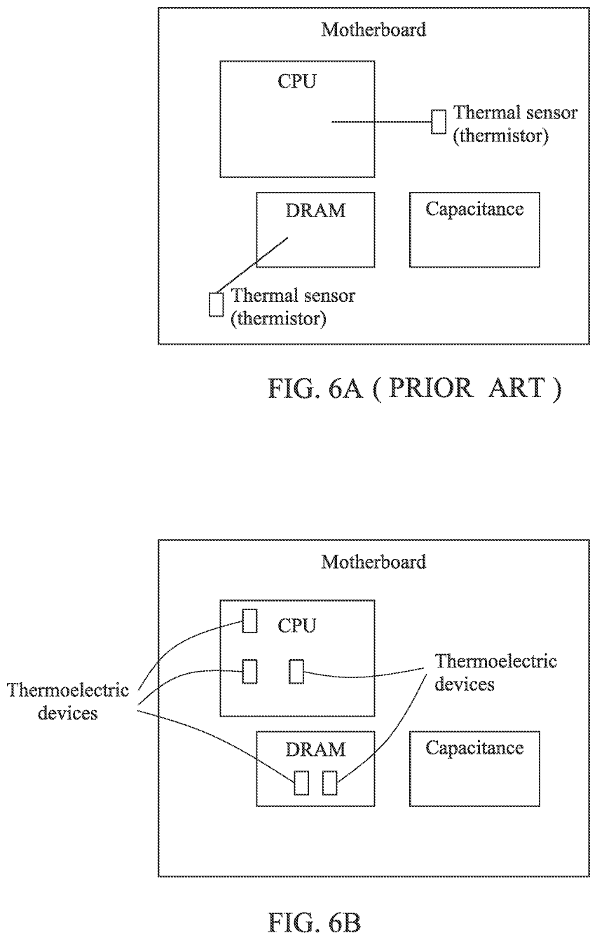

FIG. 6A is a top view of a motherboard including a central processing unit (CPU), a dynamic random access memory (DRAM), and capacitance known in the art. Referring to FIG. 6A, the thermal sensors (e.g., thermistors) are disposed external to the central processing unit and the dynamic random access memory. Therefore, the number of thermal sensors used in the motherboard is restricted by the real estate of the motherboard, and the accuracy to the thermal measurement (i.e., temperature reading) of the central processing unit and the dynamic random access memory is limited by the distance between the thermal sensors and the central processing unit and the dynamic random access memory. In contrast, embodiments of the present disclosure enable the placement of thermoelectric devices within the central processing unit and the dynamic random access memory, thereby improving temperature measurement accuracy and real estate saving in the motherboard due to the relatively small dimensions of the thermoelectric devices.

FIG. 6B is a top view of a motherboard including a central processing unit (CPU), a dynamic random access memory (DRAM), and capacitance according to an exemplary embodiment. Referring to FIG. 6B, thermoelectric devices for monitoring temperature of active regions in the central processing unit (CPU) and dynamic random access memory (DRAM) are disposed at close distances to the active regions, and thermoelectric coolers can also be disposed in the vicinity of the active regions to reduce the temperature of the central processing unit (CPU) and dynamic random access memory (DRAM). In fact, the thermoelectric devices are embedded with the central processing unit (CPU) and dynamic random access memory (DRAM) for accurately monitoring temperature changes in the CPU and DRAM.

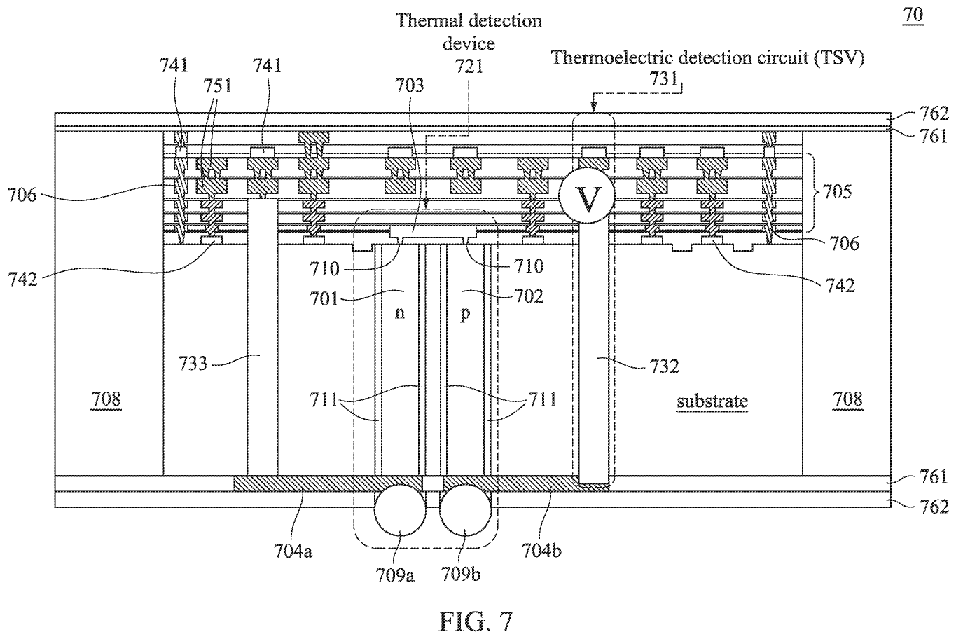

FIG. 7 is a cross-sectional view illustrating a semiconductor device 70 according to some embodiments. Referring to FIG. 7, the semiconductor device 70 includes a substrate, a plurality of semiconductor devices 712 on an upper surface of the substrate, a thermal detection device 721 and a thermoelectric detection circuit 731. The thermal detection device 721 and the thermoelectric detection circuit 731 can be configured as the thermoelectric device as shown and described in FIGS. 1A, 2A, 2B, 3A, 3B, and 4A. In the example shown in FIG. 7, only a single thermoelectric device 721 is shown, but it is understood that the single thermoelectric device is used for clarity reason and should not be limiting. In an exemplary embodiment, the semiconductor device 70 may include a plurality of active devices 742 disposed on the substrate, the active devices can include a GPU having a cluster of parallel processing units, a plurality of high power field effect transistors, laser diodes, a stack of high bandwidth memory devices, and others.

Referring to FIG. 7, the thermal detection device 721 includes a through-silicon via (TSV) structure having a first TSV 701 and a second TSV 702 extending through the substrate. The substrate may include a bulk silicon substrate or a non-semiconductor substrate. Alternatively, the substrate may include an elementary semiconductor, such as silicon or germanium in a crystalline structure, a compound semiconductor, e.g., silicon germanium, silicon carbide, gallium arsenic, gallium phosphide, indium phosphide, indium arsenide, indium antimonide, or combinations thereof. The substrate may also include a semiconductor-on-insulator (SOI) substrate. In an embodiment, the substrate is a silicon layer of an SOI substrate. The substrate can include various doped regions depending on design requirements, e.g., n-type wells and/or p-type wells. The doped regions are doped with p-type dopants, e.g., boron, n-type dopants, e.g., phosphorous, arsenic, or combinations thereof. The doped regions may be formed directly on the substrate, in a P-well structure, in an N-well structure, in a dual-well structure, on a raised structure, or in a raised structure. The substrate may also include various active regions for forming N-type metal-oxide semiconductor transistor (NMOS) devices and P-type metal-oxide semiconductor transistor (PMOS) devices. The first through-silicon via (TSV) 701 containing a first conductivity type material and the second TSV 702 containing a second conductivity type material opposite the first conductivity type material. In an embodiment, the first conductivity type material includes an n-type doped material, and the second conductivity type material includes a p-type doped material. The first and second through-silicon vias 701 and 702 may have a cylindrical shape extending from an upper surface of the substrate to a lower surface of the substrate. In an embodiment, the first and second through-silicon vias 701 and 702 may have a circular cross-section. In an embodiment, the first and second through-silicon vias 701 and 702 may have a rectangular cross-section, as indicated by dotted lines in FIG. 2A. In some embodiments, the first and second through-silicon vias 701 and 702 may have other shaped cross-sections, such as oval, square, and other polygonal-shaped cross-sections.

The semiconductor device 70 also includes a first conductive layer 703 disposed on the upper surface of the substrate and electrically coupled to the upper portion of the first and second TSVs 701 and 702. The first conductive layer 703 can include aluminum (Al), copper (Cu), tungsten (W), or highly doped polysilicon. The semiconductor device 70 further includes a second conductive layer disposed on the lower surface of the substrate and having a first portion 704a electrically coupled to the lower portion of the first TSV 701 and a second portion 704b electrically coupled to the lower portion of the second TSV 702. The second conductive layer can include aluminum (Al), copper (Cu), tungsten (W), or highly doped polysilicon.

The semiconductor device 70 also includes a plurality of intermetal dielectric layers 705 disposed on the first conductive layer 703 and on the upper surface of the substrate, and a seal ring 706 extends through the intermetal dielectric layers 705 to the substrate. The intermetal dielectric layers 705 are configured to electrically insulate metal layers 751 from each other. The intermetal dielectric layers 705 each include phosphosilicate glass (PSG) or silicon dioxide (SiO₂). The seal ring 706 is configured to shield the thermal detection device 721 from noises and electromagnetic signals generated by the active devices 742. The seal ring 706 includes one or more layers of metal, such as copper (Cu), aluminum (Al), tungsten (W), or a highly doped semiconductor material, such as n-type doped silicon, p-type doped silicon, n-type doped polysilicon, p-type doped polysilicon, or combinations thereof. In an embodiment, the seal ring 706 is connected to a DC power supply. In an embodiment, the seal ring 706 is connected to ground. In an embodiment, the seal ring 706 is in a floating state.

The semiconductor device 70 also includes a first through oxide via (TOV) 732 formed on the second portion 704b of the second conductive layer and extending through the substrate and cross a portion of the intermetal dielectric layers 705 and electrically coupled to the thermoelectric detection circuit 731. The semiconductor device 70 also includes a second through oxide via (TOV) 733 formed on the first portion 704a of the second conductive layer and extending through the substrate and cross a portion of the intermetal dielectric layers 705 and electrically coupled to the thermoelectric detection circuit 731. That is, the first and second TOVs 732 and 733 cross the substrate to electrically coupled the bottom portions of the through-silicon vias 701 and 702 to the thermoelectric detection circuit 731 which is configured to determine or measure an electrical signal (indicated by the letter “V”) generated by the thermal detection device 721 when the thermal detection device 721 has a temperature difference between its upper and lower portions. Each of the first and second TOVs 732 and 733 includes aluminum, copper, tungsten, or highly doped polysilicon. The semiconductor device 70 also includes a plurality of conductive pads 741 on the intermetal dielectric layers 705 and configured to electrically connect the seal ring 706 and the TOVs 732, 733 to a power supply.

The semiconductor device 70 also includes an around-die dielectric layer 708 surrounding the substrate. The around-die dielectric layer 708 includes tetraethyl orthosilicate (TEOS), silicon oxide (SiO₂), and the like. In an embodiment, the semiconductor device 70 also includes one or more bonding layers 761, 762 disposed on the first and second portions 704a, 704b of the second conductive layer and on the lower surface of the substrate. The bonding layers 761, 762 each include silicon oxide. In an embodiment, the semiconductor device 70 also includes a plurality of under bump metal pads 709a, 709b coupled to the first and portions 704a, 704b of the second conductive layer. In an embodiment, the under bump metal pads 709a, 709b enable measurement or monitoring of an electrical signal generated by a temperature difference between the first and second conductive layers 703, 704 by an external measurement device (not shown).

In some embodiments, the semiconductor device 70 also includes a metal silicide layer 710 disposed between the upper surface of the first and second TSVs 701 and 702 and the first conductive layer 703. The metal silicide layer 710 includes at least one metal selected from titanium (Ti), tungsten (W), cobalt (Co), nickel (Ni), hafnium (Hf), platinum (Pt), and tantalum (Ta). In an exemplary embodiment, the metal silicide layer 210 includes CoSi, NiSi, or a combination thereof. In some embodiments, the semiconductor device 70 also includes a dielectric liner 711 disposed between sidewalls of the through-silicon vias 701, 702 and the substrate. The dielectric liner 711 includes silicon oxide.

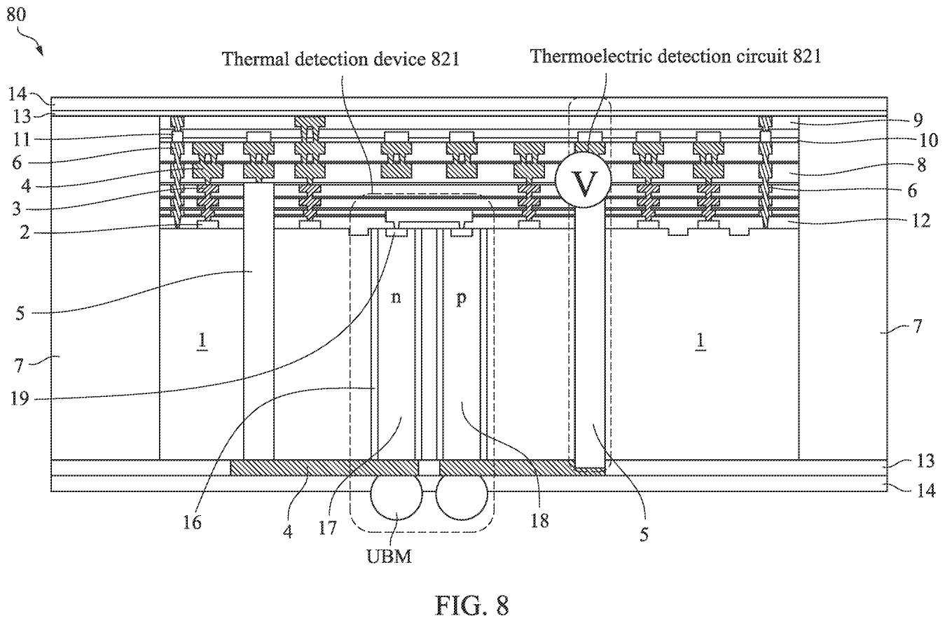

FIG. 8 is a cross-sectional view illustrating a semiconductor device 80 according to some embodiments. Referring to FIG. 8, reference numerals 1 to 19 denote the different layers and structures. Some of the features and components have been described in detail with reference to FIG. 7 and will not be repeated herein for the sake of brevity. For example, the semiconductor device 80 includes a thermal detection device 821 and a thermoelectric detection circuit 831 electrically coupled to the thermal detection device 821 through a TOV 5 and a first portion of the conductive layer 4 disposed on the lower surface of the substrate 1. A under bump metallization (UBM) structure is connected to the thermal detection device 821 including a first through-silicon via (TSV) 17 containing a first conductivity type impurity (e.g., n-type dopant) and a second through-silicon via (TSV) 18 containing a second conductivity type impurity (e.g., p-type dopant).

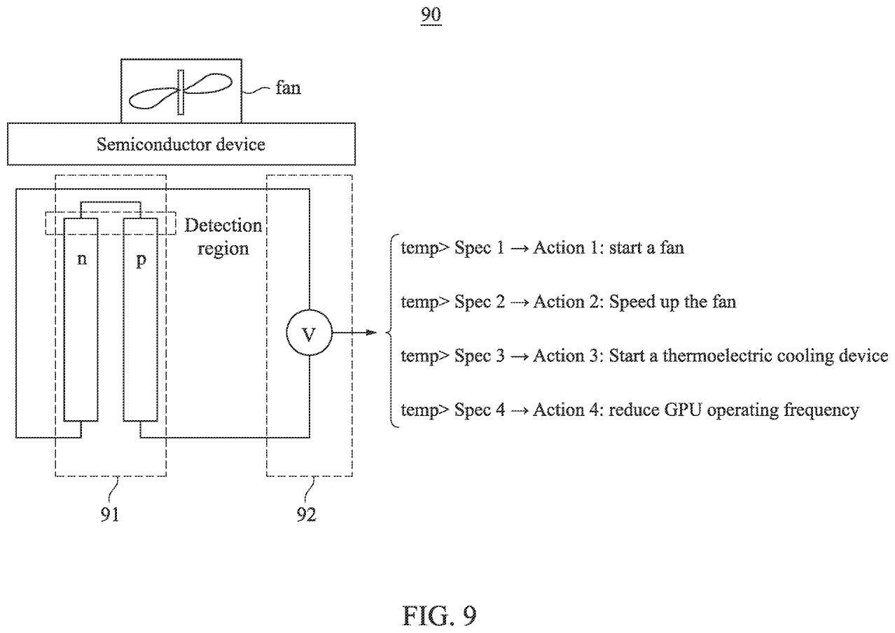

FIG. 9 is a diagram illustrating operation steps of a cooling apparatus 90 according to an exemplary embodiment. Referring to FIG. 9, the cooling apparatus 90 includes a thermal detection device 91 and a thermoelectric detection circuit 92 electrically coupled to the thermal detection device 91 that are similar or the same as the thermal detection device 721 and the thermoelectric detection circuit 731 of FIG. 7. The cooling apparatus 90 also includes a thermoelectric cooling device (not shown) that is similar or the same as the thermoelectric cooling device 30B of FIG. 3B. In an exemplary embodiment, the cooling apparatus 90 is disposed in a vicinity of a semiconductor device 93 that can be a graphics processing unit GPU. When a temperature of a detection region within the GPU exceeds a predetermined first temperature (Spec 1), the cooling system starts (activates) an electric fan (Action 1). When the temperature of the detection region within the GPU exceeds a predetermined second temperature (Spec 2>Spec 1), the cooling system speeds up the electric fan (Action 2). When the temperature of the detection region within the GPU exceeds a predetermined third temperature (Spec 3>Spec 2), the cooling system starts a thermoelectric cooling device embedded within the GPU (Action 3). When the temperature of the detection region within the GPU exceeds a predetermined fourth temperature (Spec 4>Spec 3), the cooling system reduces an operating frequency of the GPU (Action 4).

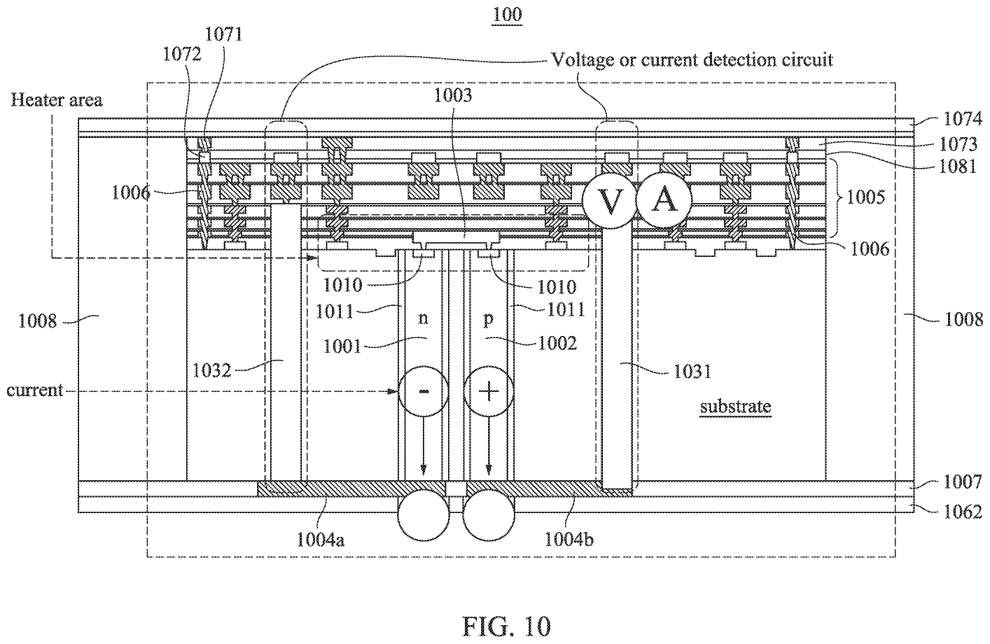

FIG. 10 is a cross-sectional view illustrating a semiconductor device 100 including a thermoelectric device and a detection circuit according to some embodiments. Referring to FIG. 10, the semiconductor device 100 includes a substrate, and a through-silicon via structure extending through the substrate and having a first through-silicon via (TSV) 1001 and a second TSV 1002. The first TSV 1001 has a first conductivity type material and the second TVS 1002 has a second conductivity type material opposite the first conductivity type material. A liner 1011 is disposed on sidewall surfaces of the first and second through-silicon vias 1001 and 1002. The liner includes a dielectric material, e.g., silicon oxide. The semiconductor device 100 also includes a first conductive layer 1003 on an upper surface of the substrate and electrically coupled to the first and second through-silicon vias 1001 and 1002 through a metal silicide 1010. The metal silicide 1010 includes at least one metal selected from titanium (Ti), tungsten (W), cobalt (Co), nickel (Ni), hafnium (Hf), platinum (Pt), and tantalum (Ta), e.g., CoSi, NiSi, or a combination thereof. In an embodiment, In an embodiment, the first and second through-silicon vias 1001 and 1002 may have a circular cross-section. In an embodiment, the first and second through-silicon vias 1001 and 1002 may have a rectangular cross-section. The first TSV 1001 includes a doped silicon material containing n-type dopants, such as nitrogen (N), phosphorous (P), arsenic (As), or combinations thereof with a doping concentration greater than 1E17 atoms/cm³. The second TSV 1002 includes a doped silicon material containing p-type dopants, such as boron (B), aluminum (Al), gallium (Ga) or combinations thereof with a doping concentration greater than 1E17 atoms/cm³.

The semiconductor device 100 also includes a plurality of intermetal dielectric layers 1005 disposed on the upper surface of the substrate and the first conductive layer 1003, a first through-oxide via (TOV) 1031 extending through the substrate and at least a portion of intermetal dielectric layers 1005, and a second through-oxide via (TOV) 1032 extending through the substrate and at least a portion of intermetal dielectric layers 1005. The first TOV 1031 is electrically coupled to a lower portion of the TSV 1002 through a portion 1004b of a second conductive layer disposed on a lower surface of the substrate, and the second TOV 1032 is electrically coupled to a lower portion of the TSV 1001 through a portion 1004a of the second conductive layer. The first and second TSVs 1001, 1002, the first conductive layer 1003, the first and second portions 1004a, 1004b of the second conductive layer form the thermoelectric device configured to determine a temperature of a heater area. The first and second TOVs 1031, 1032 each include copper. The first and second conductive layers include aluminum, copper, tungsten, or highly doped polysilicon. In an embodiment, the TOVs 1031, 1032 are electrically coupled to a detection circuit configured to detect a current or voltage generated by the thermoelectric device. The detection circuit can be the detection circuit shown and described in connection with FIG. 4B, i.e., the detection circuit may include an operational amplifier and a controller configured to perform operations steps described in FIG. 9.

Referring still to FIG. 10, the semiconductor device 100 also includes a seal ring 1006 surrounding the thermoelectric device and the detection circuit and extending from the upper surface of the substrate through the intermetal dielectric layers 1005 and through a passivation layer 1081 to connect to a metal layer 1071 through a connection pad 1072. The seal ring includes one or more layers of metal, such as copper (Cu), aluminum (Al), tungsten (W), or a highly doped semiconductor material, such as n-type doped silicon, p-type doped silicon, n-type doped polysilicon, p-type doped polysilicon, or combinations thereof. The seal ring 1006 can be connected to a DC power supply, ground, or floating. The passivation layer 1081 includes SiN, USG, or silicon oxide. The metal layer 1071 includes aluminum, copper, tungsten, and the like. A bonding layer 1073 is disposed on the passivation layer 1081, and a second bonding layer 1074 is on the bonding layer 1073. The semiconductor device 100 also includes a third bonding layer 1007 on the second conductive layer and on the lower surface of the substrate, and a fourth bonding layer 1062 on the third bonding layer 1007.

In an embodiment, an semiconductor device includes a substrate having a first surface and a second surface opposite the first surface, and a through-silicon via structure extending through the substrate. The through-silicon via structure includes a first through-silicon via containing a first conductivity type material and a second through-silicon via containing a second conductivity type material opposite the first conductivity type material. The semiconductor device also includes a first conductive layer on the first surface of the substrate and electrically coupled to a first end of the first through-silicon via and a first end of the second through-silicon via. The semiconductor device also includes a second conductive on the second surface and having a first portion coupled to a second end of the first through-silicon via and a second portion coupled to a second end of the second through-silicon via.

In an embodiment, the through-silicon via structure includes a liner disposed between the first and the second through-silicon vias and the substrate, and a metal silicide disposed between the upper surface of the first and the second through-silicon vias and the first conductive layer.

In an embodiment, an apparatus includes a fan mounted on a computing device, a first thermoelectric device embedded in the computing device, and a detection device coupled to the first thermoelectric device and the fan. The detection device is configured to determine an electrical signal generated by the first thermoelectric device and control a rotational speed of the fan in response to the electrical signal. In an embodiment, the detection device includes a detection circuit configured to compare the electrical signal with a first reference threshold to obtain a comparison result and apply a power source to a second thermoelectric device in response to the comparison result. The second thermoelectric device is configured to reduce a temperature of the computing device.

In an embodiment, a method of operating an apparatus is provided. The apparatus includes a semiconductor device, a thermoelectric device, a detection device coupled to the thermoelectric device, and a fan mounted on the semiconductor device. The thermoelectric device includes a through-silicon via structure extending through a substrate, the through-silicon via structure having a first through-silicon via containing a first conductivity type material and a second through-silicon via containing a second conductivity type material opposite the first conductivity type material. The method includes: determining, by the detection device, an electrical signal generated by the thermoelectric device, comparing the electrical signal with a first predetermined threshold to obtain a first comparison result, and adjusting a rotation speed of the fan in response to the first comparison result. The method also includes comparing the electrical signal with a second predetermined threshold greater than the first predetermined threshold to obtain a second comparison result, and reducing an operating frequency of the semiconductor device in response to the second comparison result. The method further includes comparing the electrical signal with a third predetermined threshold greater than the second predetermined threshold to obtain a third comparison result, activating a second thermoelectric device by applying a power source to the second thermoelectric device, and cooling the semiconductor device using the second thermoelectric device.

The foregoing merely outlines features of embodiments of the disclosure. Various modifications and alterations to the described embodiments will be apparent to those skilled in the art in view of the teachings herein. Those skilled in the art will appreciate that equivalent constructions do not depart from the scope of the present disclosure, and that they may make various changes, substitutions, and alterations herein without departing from the spirit and scope of the present disclosure.

What is claimed is:

1. An semiconductor device, comprising:
a substrate having a first surface and a second surface opposite the first surface;
a through-silicon via structure extending through the substrate, the through-silicon via structure comprising a first through-silicon via containing a first conductivity type material and a second through-silicon via containing a second conductivity type material opposite the first conductivity type material; and
a first conductive layer on the first surface of the substrate and comprising a first portion coupled to a first end of the first through-silicon via and a first end of the second through-silicon via.

2. The semiconductor device of claim 1, further comprising:
a second conductive layer on the second surface of the substrate and comprising a first portion coupled to a second end of the first through-silicon via and a second portion coupled to a second end of the second through-silicon via, the first and second portions of the second conductive layer being electrically isolated from each other.

3. The semiconductor device of claim 2, further comprising:
a first solder bump coupled to the first portion of the second conductive layer; and
a second solder bump coupled to the second portion of the second conductive layer.

4. The semiconductor device of claim 2, wherein the through-silicon via structure further comprises:
a third through-silicon via containing the first conductivity type material and having a first end and a second end opposite the first end;
a fourth through-silicon via containing the second conductivity type material and having a first end and a second end opposite the first end;
the first conductive layer comprising a second portion coupled to the first end of the third through-silicon via and the first end of the fourth through-silicon via; and
the second portion of the second conductive layer coupled to the second end of the third through-silicon via.

5. The semiconductor device of claim 1, further comprising:
a metal silicide layer having a first silicide portion disposed on an upper surface of the first through-silicon via, and a second silicide portion disposed on an upper surface of the second through-silicon via.

6. The semiconductor device of claim 1, further comprising:
a conformal liner on sidewalls of the through-silicon via structure.

7. The semiconductor device of claim 1, further comprising:
a detection circuit configured to determine an electrical signal that is a function of a temperature difference between the first and second surfaces of the substrate.

8. The semiconductor device of claim 1, wherein the first conductivity type material comprises n-doped silicon, and the second conductivity type material comprises p-doped silicon.

9. The semiconductor device of claim 1, further comprising:
a plurality of electronic devices on the first surface and in a vicinity of the through-silicon via structure.

10. The semiconductor device of claim 1, wherein each of the first and second through-silicon vias comprises a substantially circular or rectangular cross-section.

11. The semiconductor device of claim 1, wherein the through-silicon via structure is configured to operate as a temperature sensor.

12. The semiconductor device of claim 11, further comprising:
a second through-silicon via structure extending through the substrate, the second through-silicon via structure comprising a fifth through-silicon via containing the first conductivity type material and a sixth through-silicon via containing the second conductivity type material opposite the first conductivity type material,
wherein the fifth through-silicon via is coupled to a first terminal of a power supply, and the sixth through-silicon via is coupled to a second terminal of the power supply.

13. An apparatus comprising:
a fan mounted on a computing device;
a first thermoelectric device embedded in the computing device; and
a detection device coupled to the first thermoelectric device and the fan,
wherein the detection device is configured to determine an electrical signal generated by the first thermoelectric device and control a rotational speed of the fan in response to the electrical signal.

14. The apparatus of claim 13, wherein the detection device is further configured to reduce an operating frequency of the computing device in response to the electrical signal.

15. The apparatus of claim 13, further comprising a second thermoelectric device embedded in the computing device, wherein the detection device is further configured to activate the second thermoelectric device to cool the computing device in response to the electrical signal.

16. The apparatus of claim 13, wherein the computing device comprises a plurality of processing units disposed on a substrate, and the first thermoelectric device comprises a through-silicon via structure extending through the substrate, the through-silicon via structure comprising a first through-silicon via containing a first conductivity type material and a second through-silicon via containing a second conductivity type material opposite the first conductivity type material.

17. A method of operating an apparatus comprising a semiconductor device, a thermoelectric device, a detection device coupled to the thermoelectric device, and a fan mounted on the semiconductor device, the method comprising:
determining, by the detection device, an electrical signal generated by the thermoelectric device, the thermoelectric device comprising a through-silicon via structure extending through a substrate, the through-silicon via structure comprising a first through-silicon via containing a first conductivity type material and a second through-silicon via containing a second conductivity type material opposite the first conductivity type material;
comparing the electrical signal with a first predetermined threshold to obtain a first comparison result; and
adjusting a rotation speed of the fan in response to the first comparison result.

18. The method of claim 17, further comprising:
comparing the electrical signal with a second predetermined threshold greater than the first predetermined threshold to obtain a second comparison result; and
reducing an operating frequency of the semiconductor device in response to the second comparison result.

19. The method of claim 18, further comprising:
comparing the electrical signal with a third predetermined threshold greater than the second predetermined threshold to obtain a third comparison result;
activating a second thermoelectric device by applying a power source to the second thermoelectric device; and
cooling the semiconductor device using the second thermoelectric device.

20. The method of claim 19, wherein the thermoelectric device and the second thermoelectric device are embedded in the substrate.
